(19) United States
(12) Patent Application Publication
(10) Pub. No.: US 2016/0141442 A1
(43) Pub. Date: May 19, 2016

(54) USE OF SILICON NITRIDE AS A SUBSTRATE AND A COATING MATERIAL FOR THE RAPID SOLIDIFICATION OF SILICON

(71) Applicant: Christoph SACHS, Boston, MA (US)

(72) Inventor: Christoph Sachs, Herzogenrath (DE)

(21) Appl. No.: 14/900,884

(22) PCT Filed: Jul. 10, 2014
(86) PCT No.: PCT/US2014/046070

§ 371 Date: Dec. 22, 2015

Related U.S. Application Data
(60) Provisional application No. 61/860,598, filed on Jul. 31, 2013.

(51) Int. Cl. H01L 31/18

(52) U.S. Cl. CPC H01L 31/186; H01L 31/182

(57) ABSTRACT

Silicon nitride particles are used as a coating or substrate material for kerfless wafer making technologies.

### CROSS REFERENCE TO RELATED APPLICATION

This claims priority to and the benefit of provisional U.S. patent application Ser. No. 61/860,598 filed Jul. 31, 2013, the entirety of which is incorporated herein by reference.

### STATEMENT REGARDING FEDERALLY SPONSORED RESEARCH OR DEVELOPMENT

This invention was made with Government support under Prime Contract No. DE-FG36-08GO18008, awarded by the Department of Energy. The Government has certain rights in this invention.

### TECHNICAL FIELD

The invention generally relates to silicon nitride coatings for processing of silicon.

### BACKGROUND INFORMATION

The majority of multicrystalline silicon wafers are produced by directionally solidifying silicon in a crucible and subsequently sawing the ingot into silicon wafers. In contrast, in kerfless silicon wafer making technologies, the silicon wafer or ribbon is directly formed from the silicon melt or by recrystallization of a silicon film. In several kerfless processes, molten silicon is in contact with a substrate material during solidification. Examples of kerfless processes range from full contact as in ribbon growth on substrate (RGS) and zone melting recrystallization (ZMR) to partial contact as in crystallization on dipped substrate (CDS) to minimal contact as in string ribbon (SR).

Three requirements for a suitable substrate material include low reactivity with molten silicon, low impurity content, and non-wetting behavior. Non-wetting behavior is indicative of low nucleation rates and/or high undercooling. All of these requirements are preferably fulfilled to produce multicrystalline silicon wafers with electrical properties that are suitable for high efficiency solar cells.

The combination of the nucleation behavior of the substrate material and the thermal profile during the solidification governs the resulting microstructure of the silicon wafer, which ideally consists of large defect-free grains. Due to a favorable surface-to-volume ratio and the slow crystal growth rates (˜1 cm/h), the microstructure defined during ingot casting is less affected by the crucible material. In contrast, in kerfless wafer-making technologies, the surface-to-volume ratio is relatively small and crystal growth rates are on the order of hundreds of cm/h (e.g., ˜600 cm/h for ZMR). Consequently, the nucleation behavior of the substrate material is crucial for the evolution of the microstructure during solidification in kerfless wafer fabrication, preferably leading to the formation of large defect-free grains that are needed for acceptable electrical properties for, e.g., photovoltaic applications.

### SUMMARY

In embodiments of the invention, spherical silicon nitride particles may be used as coating or substrate materials for kerfless wafer making technologies. Bulk silicon nitride fulfills two of the above-mentioned requirements of a suitable substrate material for silicon wafer formation, namely, low reactivity with molten silicon and low impurity content. Bulk silicon nitride, however, is readily wetted by molten silicon. On the other hand, porous silicon nitride coatings or substrates made of spherical silicon nitride particles provide low nucleation rates, allowing, under appropriate processing conditions, the formation of silicon wafers with relatively large grain sizes. Lower nucleation rates create fewer nucleation sites, which leads to the formation of fewer grains with larger sizes than one would obtain with higher nucleation rates and more nucleation sites.

In an aspect, embodiments of the invention include a method of forming a kerfless multicrystalline silicon wafer that may include applying a substantially spherical silicon nitride powder to an inner surface of a mold, the mold having a closed bottom. Molten silicon may be poured into the mold. The molten silicon may be solidified by cooling the molten silicon in the mold to form the kerfless multicrystalline silicon wafer. The kerfless multicrystalline silicon wafer may be removed from the mold. A crystal growth rate during solidification may be selected from a range of 100 cm/h to 3000 cm/h.

One or more of the following features may be included. The multicrystalline silicon wafer may include grains having a grain size of at least 4 mm². The spherical silicon nitride powder may have a total bulk metal and non-metal impurity content of less than 200 ppm. The spherical silicon nitride powder may have a particle size distribution of D₅₀ selected from a range of 10 nm to 10 μm. The spherical silicon nitride powder may have a surface oxygen content of less than or equal to 50 wt % and/or include particles having a ratio of a long to a short axis of the particle of less than 3 and a sphericity value φ>0.82.

The kerfless multicrystalline silicon wafer may have a thickness of less than 1 mm. A sidewall of the mold may have a height of less than 1 mm. The substantially spherical silicon nitride powder may define a layer on the mold having a thickness of less than 200 micrometers.

Applying the substantially spherical silicon nitride powder to the inner wall of the mold may include spraying a dispersion of the powder, the dispersion being free of an organic component.

In another aspect, embodiments of the invention include a method of forming a kerfless multicrystalline silicon wafer that includes forming a layer on a surface of a silicon wafer, the layer including substantially spherical silicon nitride powder. The silicon wafer may be heated to a temperature sufficient to melt at least a portion of the silicon wafer. The molten portion of the silicon wafer may be solidified by cooling the molten silicon to define the kerfless multicrystalline silicon wafer having an average grain size larger than an average grain size of the silicon wafer.

One or more of the following features may be included. The kerfless multicrystalline silicon wafer may have a grain size of at least 4 mm². The spherical silicon nitride powder may have a total metal and non-metal impurity content of less than 200 ppm. The spherical silicon nitride powder may have a particle size distribution of D₅₀ selected from a range of 10 nm to 10 μm. The spherical silicon nitride powder may have a surface oxygen content of less than or equal to 50 wt. % and/or include particles having a ratio of a long to a short axis of the particle of less than 3 and a sphericity value φ>0.82.

A crystal growth rate during solidification may be selected form a range of 100 cm/h to 3000 cm/h. The layer may have a thickness of less than 200 micrometers. In another aspect, embodiments of the invention include a method of forming a kerfless multicrystalline silicon wafer that includes forming a layer on a surface of a substrate, the layer including substantially spherical silicon nitride powder. The layer may be dipped into molten silicon. The molten silicon may be cooled proximate to the layer to define the kerfless multicrystalline silicon wafer.

One or more of the following features may be included. The kerfless multicrystalline silicon wafer may have a grain size of at least 4 mm². The spherical silicon nitride powder may have a total bulk metal and non-metal impurity content of less than 200 ppm. The spherical silicon nitride powder may have a particle size distribution of D₅₀ selected from a range of 10 nm to 10 μm. The spherical silicon nitride powder may have a surface oxygen content of less than or equal to 50 wt % and/or include particles having a ratio of a long to a short axis of the particle of less than 3 and a sphericity value φ>0.82. The silicon wafer may be removed from the molten silicon. The silicon wafer may be separated from the layer and the substrate. A crystal growth rate during cooling may be selected from a range of 10 cm/min to 200 cm/min. A mean grain size of the kerfless multicrystalline silicon wafer may be at least 0.8 mm².

### BRIEF DESCRIPTION OF DRAWINGS

FIG. 1a is a schematic diagram illustrating solid silicon on a flat substrate with a flat line indicating an interface between solid silicon and an underlying substrate;

FIG. 1b is a schematic diagram illustrating reduced contact between silicon and a substrate made of spherical particles;

FIG. 2 is a schematic diagram illustrating the formation of a mold-based silicon wafer, in accordance with an embodiment of the invention;

FIG. 3 is a schematic diagram illustrating the formation of a silicon wafer by dipping, in accordance with an embodiment of the invention;

FIG. 4 is a schematic diagram illustrating zone melting recrystallization of a preformed silicon wafer, in accordance with an embodiment of the invention;

FIG. 5 is a schematic diagram illustrating zone melting recrystallization of a deposited silicon wafer, in accordance with an embodiment of the invention;

FIG. 6 is a schematic diagram of a wafer being processed in a zone melting furnace, in accordance with an embodiment of the invention; and

FIG. 7 is a micrograph of silicon recrystallized on silicon nitride powder in accordance with an embodiment of the invention.

### DETAILED DESCRIPTION

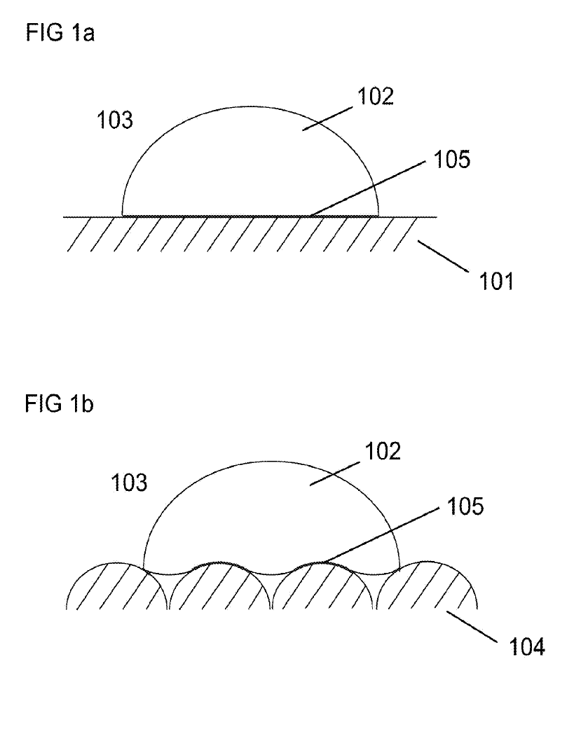

Referring to FIG. 1b, in contrast to a solid flat substrate 101 as shown in FIG. 1a, a porous coating or material made of spherical silicon nitride particles 104 is only partially wetted when it is in contact with molten silicon or, for example, a drop of molten silicon 102 in an inert atmosphere 103. Reducing the surface area 105 of a substrate or coating material in contact with the silicon melt can suppress nucleation, reduce the dissolution of the substrate material, and impede the out-diffusion of impurities from the substrate or coating material into the melt.

In addition to pure silicon nitride powder, silicon nitride powder including one or more of the following components may also be used in embodiments of the invention: boron nitride, carbon, silicon, silicon oxide, silicon carbide, silicon oxynitride and silicon oxycarbide particles. Amounts of up to 50 vol. % of these particles may be added to the silicon nitride powder to adjust coating properties such as thermal conductivity and mechanical stability.

A preferred particle shape is substantially spherical. A measure of particle sphericity is the ratio of the surface area of a sphere (with the same volume as the given particle) to the surface area of the particle.

$$ϕ = \frac{{{π}^{1 / 3} ( 6 {V}_{p} )}^{2 / 3}}{{A}_{p}}$$

Where φ=sphericity

Vₚ=volume of particle

Aₚ=surface area of particle

Another measure of sphericity is the ratio of the long axis to the short axis of a particle. In embodiments of the invention, the ratio of the long axis to the short axis of a spherical silicon nitride particle is preferably less than 3.0 and the value of φ>0.82. Furthermore, a suitable silicon nitride powder has a particle size distribution D₅₀ (i.e., size that splits the distribution, with half above and half below the indicated diameter) ranging from 10 nm to 10 μm, preferably ranging from 0.3 μm to 1 μm, and/or a surface oxygen content of at most 50 wt. %. A mean particle size of D₅₀ of less than 1 μm and a spherical particle shape may be advantageous for obtaining a stable dispersion and thus obviating the need for additives such as surfactants to avoid agglomeration of the particles. The total bulk metal impurity level in the preferred silicon nitride powder is 200 ppm or less and the total bulk non-metal content is less than 200 ppm. Higher impurity levels may contaminate the silicon wafer and consequently impair solar cell efficiency.

An oxide-containing layer, e.g., a silicon oxide or a silicon oxynitride layer, on the particle surface may further decrease the wettability of the coating and its penetration with molten silicon. Excessive oxygen may result in an increased oxygen content in the silicon wafer after solidification and hence lower solar cell efficiency after processing. Preferably, the oxygen content in the silicon wafer after processing as described herein is less than 3×10¹⁷ O atoms/cm³.

The porosity of the silicon nitride coating or substrate is preferably between 20% to 80%. The thickness of the coating is preferably less than 200 μm, more preferably less than 100 μm.

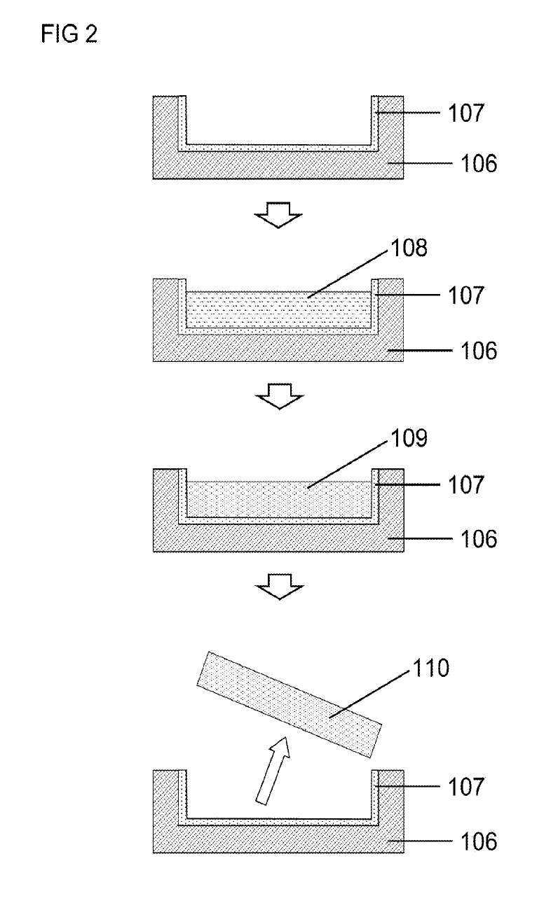

Referring to FIG. 2, in an exemplary process, a mold 106 is coated with substantially spherical silicon nitride powder 107. The mold 106 may be formed of graphite, silicon carbide, and/or silicon nitride. All of these materials are known in the art and are commonly used for components such as crucibles in the processing of silicon. Particularly, graphite can withstand high temperature, is relatively stable to molten silicon, is easily machinable, and may be produced with very low impurity contents in the ppb range. The mold 106 has a recess in the shape of the silicon wafer that is to be formed, e.g., a square recess in which the molten silicon 108 may be contained and subsequently solidified 109. The dimensions of the recess may be suitable for forming a silicon wafer 110 having dimensions useful for industrial applications, e.g., a wafer having the industry standard size for solar cells of 156 mm in width and length, and 150 μm to 250 μm in thickness; accordingly, the recess may have dimensions of, for example, 156 mm in width, 156 mm in length, and less than 1 mm in depth, e.g., 0.3 mm in depth.

Preferably, the silicon nitride powder 107 used to coat the mold is spherical, such as SN E10, available from UBE with headquarters in Tokyo, Japan. Before being applied to the mold 106, the raw silicon nitride powder may be cleaned to remove surface contamination. A possible route is wet chemical cleaning, e.g., by washing the powder in a DI water solution containing 2.5% HF and 10% HCl. The spherical silicon nitride powder may have a total bulk metal and non-metal impurity content of less than 200 ppm.

The powder is preferably in an aqueous solution, e.g., 15 wt % in DI water. The coating may be applied by, e.g., spraying an aqueous dispersion of the silicon nitride powder onto an inner wall of the mold by using a spray coating system, e.g., the FlexiCoat system, manufactured by Sono-Tek, based in Milton, N.Y. Alternatively a process such as dip coating, spin coating, brushing, or squirting may be used to apply the silicon nitride dispersion. Preferably, the dispersion is free of an organic component. Solvent-free methods include electrostatic powder coating methods. A preferred thickness of the coating is less than 200 μm, more preferably less than 100 μm: a relatively thin layer helps ensure that the coating is flat and does not crack or flake off during drying.

Silicon is placed into a crucible, e.g., a graphite or quartz crucible. The crucible may have a tundish-like design. An initial melt charge may be 5 kg and the crucible may have a dedicated area for continuous melting of silicon feedstock. The inner dimensions of the crucible may be 150 mm in width, 400 mm in length and 60 mm in depth. To facilitate continuous feeding, the silicon may be granular feedstock or silicon beads having an average diameter selected from a range of, e.g., 1-2 mm; both are commercially available from MEMO or REC. The silicon is melted by heating the crucible above the melting point of silicon of 1411° C., e.g., to 1420° C. An atmosphere of inert gas, e.g. argon or nitrogen, may be provided during the melting and subsequent casting steps to prevent oxidation of the silicon.

For casting the molten silicon, the mold 106 coated with silicon nitride powder 107 may be placed underneath a nozzle that is located at the bottom of the tundish. A stopper may be used to control the flow of molten silicon into the mold. Subsequently, the mold is moved away and a new mold may be placed underneath the tundish.

The mold 106 with the molten silicon 108 is preferably moved into a cooling zone and cooled to directionally solidify the molten silicon 109. Criteria for the preferred cooling profile are discussed below. Suitable equipment for the cooling process may be a furnace with zones of different temperatures and a rail system or belt to move the mold. A thermal profile may be imposed on the mold that allows a growth rate selected from a range of 100 cm/h to 3000 cm/h. Rapid solidification is preferable for economic reasons and to reduce the risk of melt contamination by reducing the residence time of the silicon in the molten state. The maximum growth rate is limited by the desired mean grain size of the formed silicon wafer, which is preferably at least 4 mm² with a minimum width of, e.g., 500 μm. Furthermore, the grain structure is preferably columnar, without the presence of grain boundaries parallel to a top surface. This grain structure is preferred for silicon wafers to be used in the semiconductor or solar industries for the following reason. Grain boundaries are defect areas in which carriers can recombine in semiconductors. Long carrier lifetimes are preferred for high quality semiconductor materials and high efficiency solar cells. Accordingly, relatively large, columnar grains enable long carrier lifetimes, and are preferred for many applications. As discussed below, using a silicon nitride powder coating facilitates the formation of large grains.

After cooling, the mold 106 may be flipped to remove the silicon wafer 110. If additives such as silicon oxide are not present in the coating, a thin layer of silicon nitride may remain on the silicon wafer and the remaining part will stay on the mold surface. Porous material is more likely to split, than a dense sintered layer that is typically used as a release layer. The mold may be refurbished by re-applying a thin layer of silicon nitride. The silicon nitride layer may be less than 100 μm, e.g., between 10 nm to 100 μm.

Preferably, the kerfless multicrystalline silicon wafer has a thickness of less than 1 mm. Thicker thicknesses may hinder rapid and uniform cooling.

In an alternative embodiment, rather than pouring the molten silicon from a crucible into the mold, the mold may be moved underneath a casting frame. In the ribbon growth on substrate (RGS) process, a series of graphite-based substrates move under a casting frame, which contains liquid silicon, and defines the size of the wafers and the solidification front. The process is described in detail in U.S. Pat. No. 4,670,096, incorporated herein by reference.

In yet another embodiment, silicon in the form of granular feedstock, silicon beads or silicon powder may be placed directly into the mold, melted in the mold and crystallized in the mold. An example is the Molded Wafer process from Astropower described in U.S. Pat. No. 6,111,191, incorporated herein by reference.

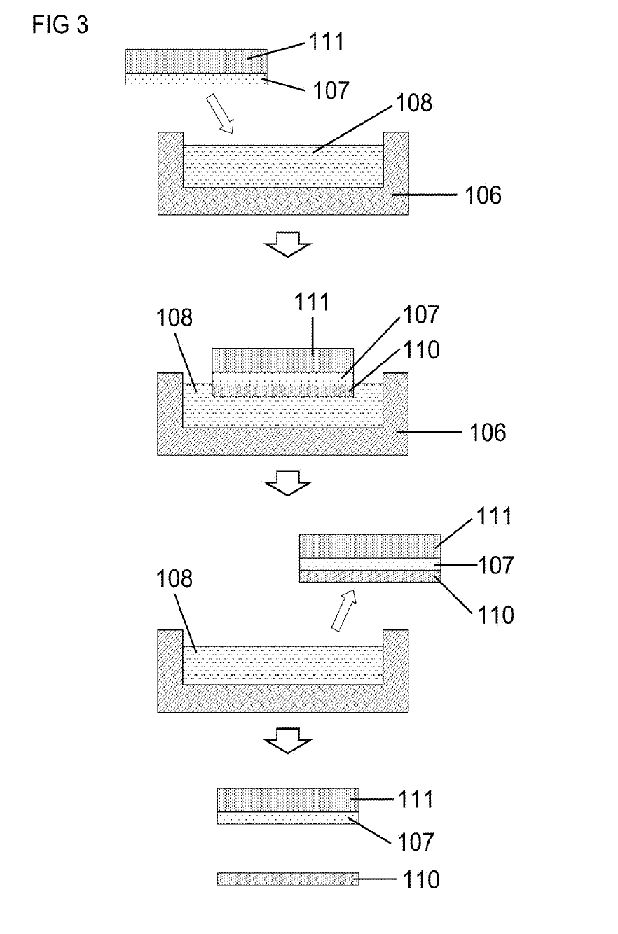

Referring to FIG. 3, in another embodiment, a silicon nitride powder may be used as a nucleation layer to form a silicon wafer from molten silicon. In particular, a substrate 111 may be coated with substantially spherical silicon nitride powder 107 in a manner similar to the methods used to coat a mold, as described above. The substrate 111 may be a graphite, silicon carbide or silicon nitride sheet with the dimensions of a standard silicon wafer used for solar cells, e.g., 156 mm square or a multiple of this dimension. The surface of the substrate may be flat or textured. The substrate 111 may then be dipped into a silicon melt 108 and a silicon wafer 110 formed on the substrate. The substrate 111 may be lifted off, and the silicon wafer 110 separated from the layer 107 and the substrate 111. A crystal growth rate during cooling may be selected from a range of 10 cm/min to 200 cm/min. A mean grain size of the formed silicon wafer may be at least 4 mm², preferably at least 0.8 mm².

The crystallization on dipped substrate (CDS) process developed by Sharp Corporation is described in detail in U.S. Pat. No. 7,186,578, incorporated herein by reference.

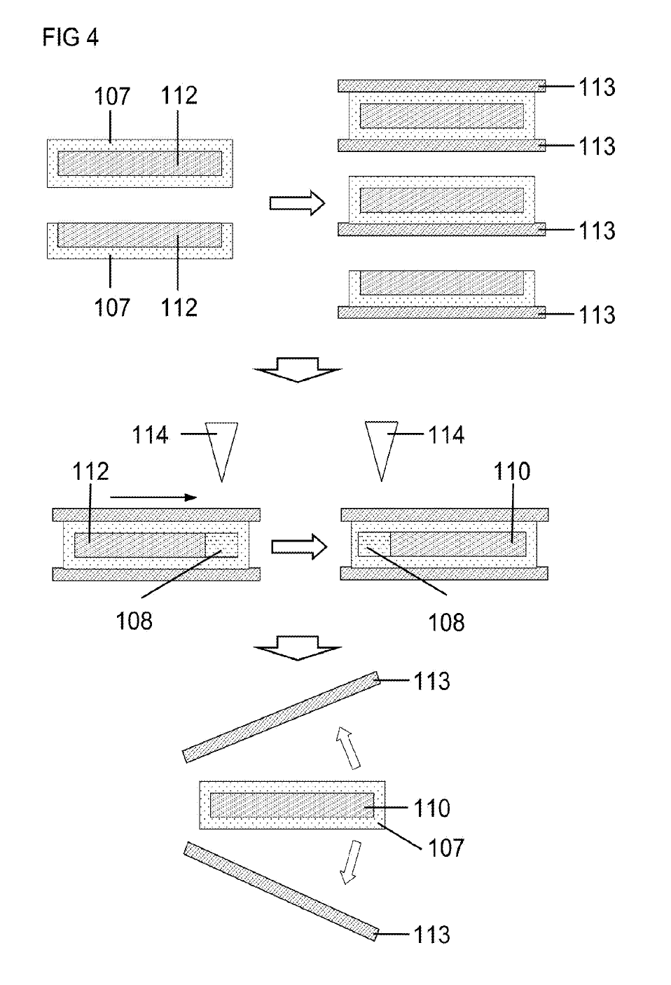

Referring to FIG. 4, in another exemplary process, a preformed silicon wafer 112 is provided. The silicon wafer 112 may be, for example, a multicrystalline wafer made by a rapid solidification, a green body formed from silicon powder, or a wafer formed by a gas phase deposition method. The wafer 112 may have an average grain size of less than a desired final grain size, e.g., an average grain size of less than 4 mm².

For example, silicon fines, readily available from MEMC, may be used to produce preformed silicon wafers. The silicon powder may be hot-pressed to sinter the silicon powder together, in accordance with well know techniques in the processing of ceramic powders.

The silicon wafer 112 may be coated with a thin layer of high-purity silicon nitride powder 112, e.g., SN E10 available from UBE. The powder is preferably in an aqueous solution, e.g., 15 wt % in DI water. The coating may be applied by, e.g., spraying an aqueous dispersion of the silicon nitride powder onto the preformed silicon wafer using a spray coating system, e.g., the FlexiCoat system, manufactured by Sono-Tek, based in Milton, N.Y. Alternatively a process such as dip coating, spin coating, brushing, or squirting may be used to apply the silicon nitride dispersion. Solvent-free methods include electrostatic powder coating methods.

Before, during, and after the application of the coating, the silicon wafer may be kept at a temperature above the boiling point of water, i.e., 120° C. so that the coating dries out quickly, i.e., within several seconds after application.

The silicon nitride coating 107 may be applied to one or both sides of the silicon wafer. If the top surface of the wafer is not coated, a capping layer of, e.g., silicon oxide or silicon nitride may be preferred to improve wetting and to avoid “balling-up” of molten silicon during processing.

Preferably, a thickness of the layer is less than 200 micrometers to help prevent flaking off and cracking of the coating during drying.

The silicon wafer 112 with the silicon nitride power coating 107 may then be subjected to ZMR. The wafer may be placed on a substrate 113 or sandwiched between two substrates 113 before ZMR. The substrates 113 may be made of a refractory material such as silicon carbide or silicon nitride. Suitable dimensions are 160 mm square and a thickness between 0.5 mm and 3 mm.

ZMR methods allow the creation of a narrow molten zone 108 that is moved across the silicon wafer or silicon film. ZMR may be employed for grain enlargement. The ZMR furnace typically has a pre-heat zone, a melting zone, a solidification zone, and a cooling zone. Heating methods include IR heating, and/or resistive heating or inductive heating. In particular, the concentrated heat source 114 of a ZMR system may be an electron beam, a laser, graphite or silicon carbide strip for resistive heating, or an incoherent lamp heater. A suitable zone melting furnace is described below in further detail with respect to Example 1.

The silicon wafer 112 may be moved through the pre-heat zone and partially or completely melted in the melting zone by being heated to a temperature of 1420° C., and then solidified in the zone melting furnace. To directionally grow large silicon grains, a well-defined thermal profile is preferably imposed on the molten silicon film during solidification of the silicon wafer 110. For optimal grain growth conditions the thermal gradient at the solid-liquid interface may be biased in the pull direction, i.e., the travel direction of the silicon wafer or ribbon, in the normal direction of the silicon wafer, and in the perpendicular direction. A convex solid-liquid interface shape allows grains to grow outward and increase in size. If a thermal gradient is not biased, new grains may nucleate from the silicon melt and the resulting wafer may be small grained and exhibit inferior electronic properties. A well defined thermal profile ensures that existing grains preferentially grow and that new grains are less likely to evolve.

The thermal gradient imposed on the silicon melt in the solidification zone is preferably steep to limit the amount of area available for nucleation and to create stable growth of the solidification interface. The solidification zone is defined as the region in which there is molten silicon that is undercooled below its respective melt temperature. Because silicon can dendritically grow very quickly into an undercooled melt, the solidification zone is preferably compact to allow for large, coarse grains. Specifically, the solidification zone is preferably no more than 3 cm in length in the pull direction. Furthermore, the melt in the solidification zone is preferably at least 0.5° C. above the melting temperature of silicon. Therefore, the minimum thermal gradient in a directional solidification process is preferably at least 0.16 K/cm. As the level of undercooling in the solidification zone scales with the process rate, which may range from of 100 cm/h to 3000 cm/h, higher levels of undercooling and correspondingly steeper thermal gradients may be necessary.

The resulting microstructure may include elongated grains that are typically several millimeters wide and several centimeters long. The obtained grain size is interdependent on the nucleation behavior of the coating material and the thermal profile in the solidification zone. Preferably, wherein the kerfless multicrystalline silicon wafer has a grain size has an average grain size larger than an average grain size of the original silicon wafer, e.g., at least 4 mm².

Silicon nitride coatings, as used in embodiments of the invention, provide key advantages over silicon oxide coatings. Although silicon oxide coatings are known to have smaller nucleation rates leading to larger grain sizes, the contamination of the silicon wafer with oxygen during ZMR may impair the material quality and outweigh the benefit of the larger grain size. For example, oxygen levels above 3×10¹⁷ O atoms/cm³ may significantly reduce the final solar cell efficiency. In contrast, silicon nitride is more stable in contact with molten silicon; nitrogen is also not considered to affect the electronic properties of silicon wafers.

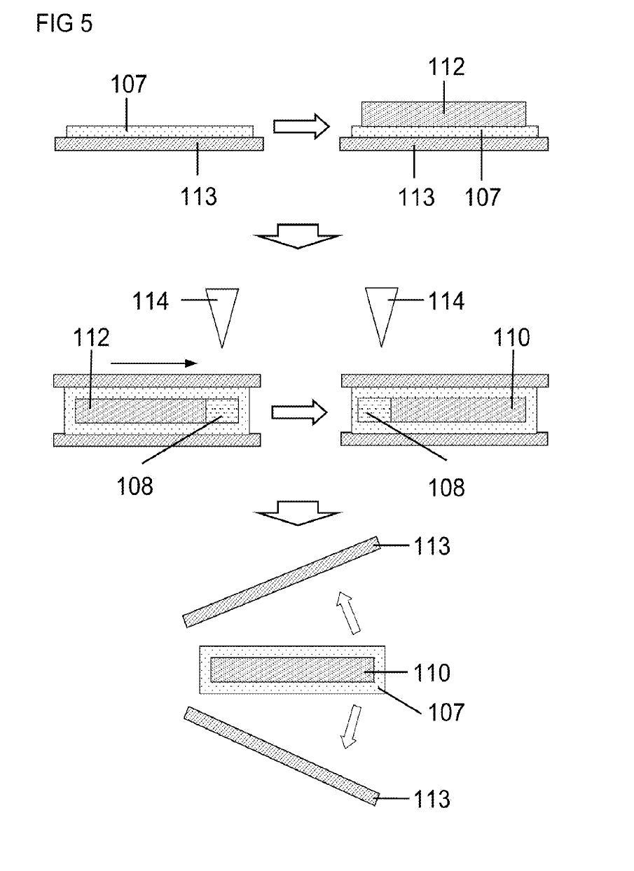

Referring to FIG. 5, in some embodiments, rather than using a preformed silicon wafer with ZMR, a deposited silicon wafer 112 may be utilized. In particular, spherical silicon nitride powder 107 may be applied to a substrate 113, which may include a refractory material such as silicon carbide or graphite. A typical dimension may be 156 mm square or a multiple of this dimension. A silicon wafer 112 may be formed on the substrate by a gas phase deposition method such as by CVD. A suitable commercially available equipment is the Tystar Mini Tytan 4600 CVD system or a CVD system custom-built by centrotherm photovoltaics, Germany. The thickness of the deposited silicon layer is preferably 200 μm, thereby allowing the formation of a 200 μm thick silicon wafer after ZMR, which can then be processed in standard photovoltaic cell lines. Additionally, a capping coating of silicon nitride may be applied to the silicon wafer. The deposited silicon wafer may be subjected to zone melting recrystallization in the same manner as described above with respect to preformed silicon wafers.

### Example 1

The effect of using silicon nitride powder to influence the grain size in a silicon wafer was demonstrated by forming grains in a monocrystalline silicon wafer as follows. The starting material used was an as-sawn monocrystalline silicon wafer having dimensions of 156 mm×156 mm and 200 μm thick, available from REC with headquarters in Norway. The silicon wafer was cleaved into 1″ wide and 4″ long pieces and coated with a thin layer of high-purity silicon nitride powder (SN E10 from UBE). The powder was in an aqueous solution, i.e., 15 wt % in DI water. The coating was applied by spraying the aqueous dispersion of the silicon nitride powder onto the silicon wafer using an airbrush. Before, during, and after the application of the coating, the silicon wafer was kept at a temperature above the boiling point of water, i.e., 120° C. so that the coating dried out quickly, i.e., within several seconds after application.

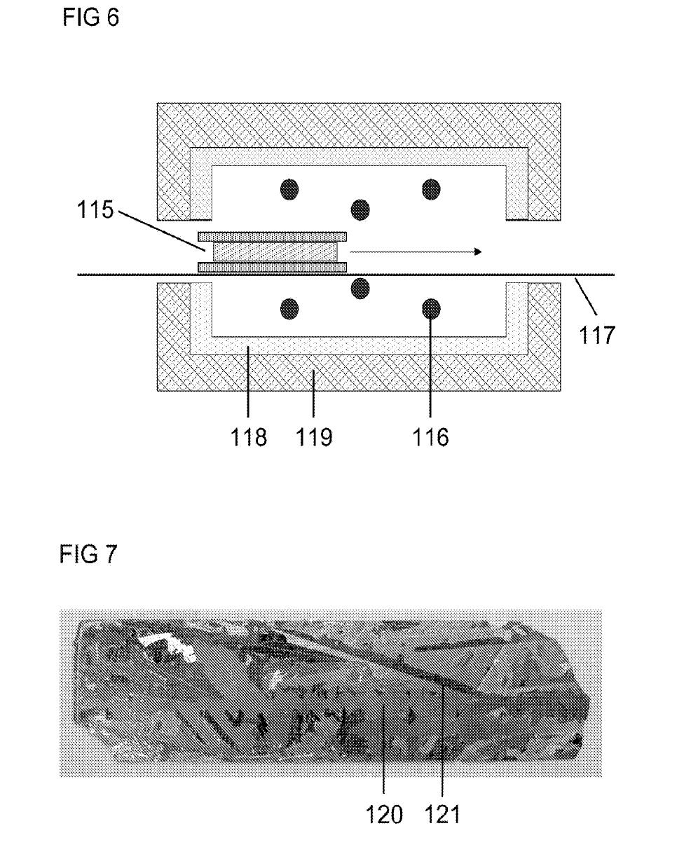

Referring to FIG. 6, the silicon wafer with the silicon nitride power coating was then subjected to zone-melting recrystallization. The coated silicon wafer 115 was sandwiched between two substrate plates, specifically 1.5 mm thick silicon carbide plates. These plates can be created from tiles that are available from Saint Gobain and that are called “Hexology SE” by Saint Gobain. The sandwiched wafer 115 then was placed in the pre-heat zone of the zone melting furnace. The stack was moved at a rate of 60 mm/min through the melting and solidification zone. The temperature set point of the heater was 1660° C., creating a thermal gradient at the solid-liquid interface amounting to 5 K/mm. The ambient atmosphere was air but may also be an inert gas such as argon or nitrogen.

The ZMR furnace utilized in this example includes six parallel heater elements 116 that are arranged in two horizontal rows, between which the wafer is passed, to create the hot zone. The clearance between the rows is 12 mm. These heater elements 116, which are spaced 25 mm apart, are resistively heated in pairs (left, middle, and right) and their temperatures are controlled with the feedback of three two-color pyrometers that monitor the temperature of the top row of elements. Thus, different thermal profiles can be created in the hot zone by adjusting the temperatures of the different heater pairs. Two parallel silicon carbide rods 117 are moved through the center of the furnace, and the wafer assembly rests on these bars during zone-recrystallization. The slider bar movement is motor-driven and samples can typically be pulled through the hot zone at a speed ranging from 10 mm/min to 120 mm/min. The heating elements and the carrier rods can be made from a rod of silicon carbide with a diameter of 3.2 mm. Such a rod is available from Saint Gobain and is called “Hexology SE” by Saint Gobain. The furnace enclosure comprises a rectangular quartz tube 118 and an outer layer of refractory insulation 119.

Referring to FIG. 7, silicon recrystallized on silicon nitride powder 107 had a resulting grain size on the order of several to tens of millimeters and was similar to the grain sizes obtained with silicon oxide coatings, which are known to have low nucleation rates. The grains 120 of the recrystallized silicon wafer were elongated in the traveling direction through the melting and solidification zone. The grain boundaries 121 were aligned in the same direction and mostly straight-lined.

In contrast, earlier experiments with 160 nm thick bulk silicon nitride coatings formed on the identical monocrystalline silicon wafers by plasma enhanced chemical vapor deposition (“PECVD”) using a Cirrus 150 machine from Nexx Systems, resulted in grain size in the low millimeter range.

Accordingly, the formation of the relatively large grains by the use of spherical silicon nitride powder demonstrates the effectiveness of the method for making silicon wafers with desired grain sizes. The point that the starting material in the described example was a monocrystalline silicon wafer whereas the method is intended for increasing the grain sizes in multicrystalline silicon wafers with initially small grain sizes is irrelevant, as the silicon wafer is melted during the zone-melting recrystallization process, and the initial grain size does not influence the resulting grain size.

The described embodiments of the invention are intended to be merely exemplary and numerous variations and modifications will be apparent to those skilled in the art. All such variations and modifications are intended to be within the scope of the present invention as defined in the appended claims.

1. A method of forming a kerfless multicrystalline silicon wafer, the method comprising the steps of:
applying a substantially spherical silicon nitride powder to an inner surface of a mold, the mold having a closed bottom,
pouring molten silicon into the mold,
solidifying the molten silicon by cooling the molten silicon in the mold to form the kerfless multicrystalline silicon wafer;
removing the kerfless multicrystalline silicon wafer from the mold,
wherein a crystal growth rate during solidification is selected from a range of 100 cm/h to 3000 cm/h.

2. The method of claim 1, wherein the multicrystalline silicon wafer comprises grains having a grain size of at least 4 mm².

3. The method of claim 1, wherein the spherical silicon nitride powder has a total bulk metal and non-metal impurity content of less than 200 ppm.

4. The method of claim 1, wherein the spherical silicon nitride powder has a particle size distribution of D₅₀ selected from a range of 10 nm to 10 μm.

5. The method of claim 1, wherein the spherical silicon nitride powder has a surface oxygen content of less than or equal to 50 wt %.

6. The method of claim 1, wherein the substantially spherical silicon nitride powder comprises particles having a ratio of a long to a short axis of the particle of less than 3 and a sphericity value φ>0.82.

7. The method of claim 1, wherein the kerfless multicrystalline silicon wafer has a thickness of less than 1 mm.

8. The method of claim 1, wherein a sidewall of the mold has a height of less than 1 mm.

9. The method of claim 1, the substantially spherical silicon nitride powder defines a layer on the mold having a thickness of less than 200 micrometers.

10. The method of claim 1, wherein applying the substantially spherical silicon nitride powder to the inner wall of the mold comprises spraying a dispersion of the powder, the dispersion being free of an organic component.

11. A method of forming a kerfless multicrystalline silicon wafer, the method comprising the steps of:
forming a layer on a surface of a silicon wafer, the layer comprising substantially spherical silicon nitride powder;
heating the silicon wafer to a temperature sufficient to melt at least a portion of the silicon wafer; and
solidifying the molten portion of the silicon wafer by cooling the molten silicon to define the kerfless multicrystalline silicon wafer having an average grain size larger than an average grain size of the silicon wafer.

12. The method of claim 11, wherein the kerfless multicrystalline silicon wafer has a grain size of at least 4 mm².

13. The method of claim 11, wherein the spherical silicon nitride powder has a total metal and non-metal impurity content of less than 200 ppm.

14. The method of claim 11, wherein the spherical silicon nitride powder has a particle size distribution of D₅₀ selected from a range of 10 nm to 10 μm.

15. The method of claim 11, wherein the spherical silicon nitride powder has a surface oxygen content of less than or equal to 50 wt. %.

16. The method of claim 11, wherein the substantially spherical silicon nitride powder comprises particles having a ratio of a long to a short axis of the particle of less than 3 and a sphericity value φ>0.82.

17. The method of claim 11, wherein a crystal growth rate during solidification is selected form a range of 100 cm/h to 3000 cm/h.

18. The method of claim 11, wherein the layer has a thickness of less than 200 micrometers.

19. A method of forming a kerfless multicrystalline silicon wafer, the method comprising the steps of:
forming a layer on a surface of a substrate, the layer comprising substantially spherical silicon nitride powder;
dipping the layer into molten silicon; and
cooling the molten silicon proximate to the layer to define the kerfless multicrystalline silicon wafer.

20. The method of claim 19, wherein the kerfless multicrystalline silicon wafer has a grain size of at least 4 mm².

21. The method of claim 19 wherein the spherical silicon nitride powder has a total bulk metal and non-metal impurity content of less than 200 ppm.

22. The method of claim 19 wherein the spherical silicon nitride powder has a particle size distribution of D₅₀ selected from a range of 10 nm to 10 μm.

23. The method of claim 19 wherein the spherical silicon nitride powder has a surface oxygen content of less than or equal to 50 wt %.

24. The method of claim 19, wherein the substantially spherical silicon nitride powder comprises particles having a ratio of a long to a short axis of the particle of less than 3 and a sphericity value φ>0.82.

25. The method of claim 19, further comprising removing the silicon wafer from the molten silicon.

26. The method of claim 25, further comprising separating the silicon wafer from the layer and the substrate.

27. The method of claim 19, wherein a crystal growth rate during cooling is selected from a range of 10 cm/min to 200 cm/min.

28. The method of claim 19, wherein a mean grain size of the kerfless multicrystalline silicon wafer is at least 0.8 mm².
